(19) United States
(12) Patent Application Publication
(10) Pub. No.: US 2025/0092574 A1
(43) Pub. Date: Mar. 20, 2025

(54) SILICON POWDER FORMING METHOD, SILICON BLOCK AND USE THEREOF

(71) Applicant: TCL ZHONGHUAN RENEWABLE ENERGY TECHNOLOGY CO., LTD., Tianjin (CN)

(72) Inventors: Lin WANG, Tianjin (CN); Guoqing FAN, Tianjin (CN); Zhi YANG, Tianjin (CN); Haoyang WU, Tianjin (CN); Long XIANG, Tianjin (CN); Lei LI, Tianjin (CN)

(73) Assignee: TCL ZHONGHUAN RENEWABLE ENERGY TECHNOLOGY CO., LTD., Tianjin (CN)

(21) Appl. No.: 18/555,444

(22) PCT Filed: Sep. 4, 2023
(86) PCT No.: PCT/CN2023/116741

§ 371 Date: Oct. 13, 2023

(51) Int. Cl. C30B 35/00; C30B 15/00; C30B 29/06

(52) U.S. Cl. CPC C30B 35/007; C30B 15/00; C30B 29/06

(57) ABSTRACT

A silicon powder forming method, a silicon block, and a use thereof are provided, which relates to technical field of single crystal growth. The silicon powder forming method according to the present application includes: placing a mold filled silicon powder in a condition for first pressure P₁ for a first pressure time T₁ to obtain a silicon block, wherein the first pressure P₁ and the first pressure time T₁ satisfy: 50 MPa≤P₁≤600 MPa, 7 min≤T₁≤15 min. By pressure control, the molded silicon block is easily removed from the mold without crushing dust. The silicon block obtained is easy to crush upon charging, and the particle size distribution of the crushed silicon block is easy to control, resulting in raising less. The silicon block obtained can be directly used for production of Czochralski single crystal, and the charge density is increased to 0.18 g/cm³˜0.25 g/cm³.

### TECHNICAL FIELD

The present application relates to the technical field of single crystal growth, and more particularly, to a silicon powder forming method, a silicon block, and a use thereof.

### BACKGROUND

Raw polycrystalline silicon powder has a small particle size (0.1 μm to 1000 μm), thus, charge density of the raw polycrystalline silicon powder is low, that is, the raw polycrystalline silicon powder is charged less in weight in same space, which directly affects weight of crucible of Czochralski single crystal furnace before use. Further, the raw polycrystalline silicon powder cannot be applied with re-feeding in the Czochralski single crystal furnace (continuous feeding and pulling crystal technology).

### Technical Problem

The present application provides a silicon powder forming method, a silicon block, and an application thereof, and solves a problem that the present silicon powder cannot be directly applied to production of Czochralski single crystal.

### Technical Solution

According to a first aspect of the present application, a silicon powder forming method includes:

placing a mold filled silicon powder in a condition for first pressure P₁ for a first pressure time T₁ to obtain a silicon block, wherein the first pressure P₁ and the first pressure time T₁ satisfy: 50 MPa≤P₁≤600 MPa, 7 min≤T₁≤15 min.

In an embodiment, the condition for first pressure P₁ is achieved by boosting, and the boosting includes: boosting a pressure to the first pressure P₁ at a first boosting rate v₁, wherein the first boosting rate v₁ satisfies: 20 MPa/s≤v₁≤30 MPa/s.

In an embodiment, the mold filled with the silicon powder is placed in a closed environment prior to the condition for first pressure P₁.

In an embodiment, the first pressure P₁ is applied by a pressurizing medium, the pressurizing medium is a fluid, and the mold (1) filled with the silicon powder is placed in a cavity prior to the condition for first pressure P₁;

the mold and the pressurizing medium are separated by the cavity; or the pressurizing medium is filled in the cavity, and the mold is in contact with the pressurizing medium.

In an embodiment, in a case that the mold and the pressurizing medium are separated by the cavity, the pressurizing medium is a liquid; and in a case that the pressurizing medium is filled in the cavity, and the mold is in contact with the pressurizing medium, the pressurizing medium is gas.

In an embodiment, in the case that the mold (1) and the pressurizing medium are separated by the cavity, an interior of the cavity maintains a dry environment with a temperature ranging from 20° C. to 25° C. and a humidity ranging from 40% rh to 50% rh. The rh is the relative humidity.

In an embodiment, the silicon powder has a particle size of 0.1 μm to 1000 μm.

In an embodiment, the mold includes a first side, a second side, and a third side; the first side is disposed opposite to the second side, the first side is connected to the second side by the third side, and the first side and the third side receive the first pressure P₁.

In an embodiment, the first side, the second side, and the third side receive the first pressure P₁, and a pressure deviation PD applied to the first side, the second side, and the third side satisfies: −5 MPa≤PD≤5 MPa.

In an embodiment, the mold includes a cover and a cylinder, the cover covers the cylinder, and the silicon powder is filled in the cylinder.

In an embodiment, the mold includes a protective sheet provided on an outer periphery of the cover, the protective sheet covers at least a part of the cover.

In an embodiment, an edge of the cover has a step, and the step surrounds the cover.

In an embodiment, the mold is made of a polyurethane material, and the polyurethane material has a density ρ₀ satisfying: 1.00 g/cm³≤ρ₀≤1.01 g/cm³.

In an embodiment, wear rate G of the mold (1) satisfies: G<G₀, wherein G₀ is material decrement in g/cm², and

G₀ satisfies: 0<G₀≤0.1 g/cm².

In an embodiment, the method includes: placing the mold (1) filled with the silicon powder to a second pressure P₂ for a second pressure time T₂, wherein the second pressure P₂ and the second pressure time T₂ satisfy: 50 MPa≤P₂≤200 MPa, 3 min≤T₂≤7 min; and
placing the mold (1) filled with the silicon powder to a third pressure P₃ for a third pressure time T₃, wherein the third pressure P₃ and the third pressure time T₃ satisfy: 200 MPa≤P₃≤600 MPa, 4 min≤T₃≤8 min.

In an embodiment, the method includes placing the mold (1) filled with the silicon powder to a fourth pressure P₄ for a fourth pressure time T₄, wherein the fourth pressure P₄ and the fourth pressure time T₄ satisfy: 100 MPa≤P₄≤600 MPa, 3 min≤T₄≤6 min.

In an embodiment, at end of pressurization, applying a first pressure relief process to the mold (1), wherein the first pressure relief process includes reducing the pressure to a fifth pressure P₅ for a time Tₙ, and the fifth pressure P₅ and the time Tₙ satisfy: 10 MPa≤P₅≤100 MPa, 1 min≤Tₙ≤2 min.

According to a second aspect of the present application, a silicon block is prepared by the above method.

In an embodiment, the silicon block is crushed to form first particles, mass percentage of the first particles in the silicon block is equal to or greater than 97%, and a particle size D₁ of each of the first particles satisfies: 10 mm≤D₁.

In an embodiment, the silicon block is crushed to form second particles, mass percentage of the second particles in the silicon block is equal to or less than 3%, and a particle size D₂ of each of the second particles satisfies: D₂<10 mm.

According to a third aspect of the present application, a use of the silicon block obtained by the above method in production of Czochralski single crystal; or a use of the above silicon block in production of Czochralski single crystal.

### Beneficial Effect

The present application provides a silicon powder forming method according to an embodiment of the present application, which has at least the following technical effects:
(1) according to the present application, the molded silicon block is easily taken out from the mold through pressure control; further, the silicon block obtained by the present application is easy to crush upon charging, and the particle size distribution of the crushed silicon block is easy to control, resulting in raising less dust;
(2) the silicon block obtained in the present application can be directly used for production of Czochralski single crystal, and the charge density is increased to 0.18 g/cm³˜0.25 g/cm³.

### BRIEF DESCRIPTION OF THE DRAWINGS

In order to make the embodiments of the present disclosure or the technical solutions in the prior art more clearly, reference will now be made to the accompanying drawings used in the description of the embodiments or the prior art, and it will be apparent that the accompanying drawings in the description below are merely some of the embodiments of the present disclosure, and other drawings may be made to those skilled in the art without any inventive effort.

FIG. 1 is an explosive perspective view of a mold according to an embodiment of the present application;

FIG. 2 is an explosive schematic view of a mold according to an embodiment of the present application;

FIG. 3 is a front view of a mold according to an embodiment of the present application;

FIG. 4 is a cross-sectional view of B-B of FIG. 3.

Reference numerals: 1—mold, 100—cylinder, 110—first side, 120—second side, 130—third side, 200—cover, 201—step, 300—protective sleeve.

### DETAILED DESCRIPTION OF THE EMBODIMENTS

In the following, the technical solutions in the embodiments of the present application is clearly and completely described in connection with the accompanying drawings in the embodiments of the present application. It should be understood that the described embodiments are merely a part of embodiments applied with the present application, rather than all embodiments. Based on the embodiments described in the present application, all other embodiments obtained by a person skilled in the art without involving any inventive effort are within the scope of the present application.

In preparation process of a crystal bar, silicon powder cannot be directly feed, and it is necessary to prepare the silicon powder into a silicon bar or a silicon block. In order to improve the charge rate, the present application provides a silicon powder forming method, including: placing a mold 1 containing silicon powder under a condition for first pressure P₁ for a first pressure time T₁, wherein the first pressure P₁ and the first pressure time T₁ satisfy: 50 MPa≤P₁≤600 MPa, 7 min≤T₁≤15 min; and obtaining a silicon block. For example, the value of the first pressure P₁ (MPa) may be 50, 100, 150, 200, 250, 300, 350, 400, 450, 500, 550, 600, or a range between any two values above. For example, the value of the first pressure time T₁ (min) may be 7, 8, 9, 10, 11, 12, 13, 14, 15, or a range between any two values above. With a low pressure for the pressurization, the pellet density is affected and labor time is consumed. With a high pressure for the pressurization, although it does not affect the pellet density of the product, the high pressure affects the life of the equipment, thereby causing difficulty in crushing the silicon block after molding.

In some embodiments, the condition for first pressure P₁ is achieved by boosting pressure, and the step for boosting pressure includes raising a pressure to the first pressure P₁ at a first boosting rate v₁, wherein v₁ satisfies: 20 MPa/s≤v₁≤30 MPa/s. For example, the value of the first boosting rate v₁ (MPa/s) may be any value of 20, 25, 30, or a range between any two values above.

In some embodiments, the mold 1 filled with the silicon powder is placed in a closed environment before reaching the condition for first pressure P1.

According to the present application, the mold 1 filled with silicon powder is placed in a closed environment. In some embodiments, a cover provided outside the mold 1 seals the mold 1, and the sealed mold 1 is subjected to a pressurization. The present application overcomes the problems that a low production efficiency is caused by every manual bagging and unbagging operations when wet pressure is applied. In addition, the wet pressure is performed by liquid transmission to press and mold the body. During the pressing, if the mold 1 is broken, the liquid can easily invade the pressed product, thereby causing product pollution and affecting the quality. The present application reduces the risk of contamination of the silicon powder by further providing an enclosed space on the periphery of the mold 1.

In some embodiments, the condition for the first pressure P1 is achieved by applying the first pressure P1 through a pressurizing medium, and the pressurizing medium is a fluid. The mold 1 filled with the silicon powder is placed in a cavity before the condition for the first pressure P1 is achieved.

The mold 1 and the pressurizing medium are separated by the cavity. Alternatively, the pressurized medium is filled in the cavity, and the mold 1 is in contact with the pressurized medium.

In some embodiments, the mold 1 and the pressurized medium are separated by the cavity, and the pressurized medium is liquid.

In some embodiments, the pressurized medium is filled in the cavity, the mold 1 is in contact with the pressurized medium, and the pressurized medium is gas.

In some embodiments, in a case that the mold and the pressurizing medium are separated by the cavity, the interior of the cavity maintains a dry environment with a temperature ranging from 20° C. to 25° C. and a humidity ranging from 40% rh to 50% rh. For example, the temperature of the dry environment may be 20° C., 21° C., 22° C., 23° C., 24° C., 25° C., or a range between any two values above. The humidity (% rh) may be 40, 41, 42, 43, 44, 45, 46, 47, 48, 49, 50, or a range between any two values above.

In some embodiments, the silicon powder has a particle size ranging from 0.1 μm to 1000 μm. For example, the particle size (μm) of the silicon powder has a value of 0.1, 10, 50, 100, 150, 200, 250, 300, 350, 400, 450, 500, 550, 600, 650, 700, 750, 800, 850, 900, 950, 1000, or a range between any two values above.

In some embodiments, the mold 1 includes a first side 110, a second side 120, and a third side 130. The first side 110 is oppositely disposed to the second side 120, and the first side 110 and the second side 120 are connected by the third face 130. The first side 110 and the third side 130 receive the first pressure P₁.

In some embodiments, the pressure deviation PD of the first pressure P1 satisfies: −5 MPa≤PD≤5 MPa. The PD (MPa) may be −5, −3, −2, 0, 1, 3, 5, or a range between any two values above.

In some embodiments, the mold filled with the silicon powder is placed under a condition for second pressure P₂ for a second pressure time T₂, and the second pressure P₂ and the second pressure time T₂ satisfy: 50 MPa≤P₂≤200 MPa, 3 min≤T₂≤7 min. For example, the value of the second pressure P2 (MPa) may be 50, 100, 150, 200, or a range between any two values above; the value of the second pressure time T2 (min) is may be 3, 4, 5, 6, 7, or a range between any two values above.

In some embodiments, the mold filled with the silicon powder is placed under a condition for third pressure P₃ for a third pressure time T₃, and the third pressure P₃ and the third pressure time T₃ satisfy: 200 MPa≤P₃≤600 MPa, 4 min≤T₃≤8 min. In a case that the value of the third pressure P₃ (MPa) is 200, 250, 300, 350, 400, 450, 500, 550, 600 or a range between any two values above, the value of the third pressure time T₃ (min) is 4, 5, 6, 7, 8, or a range between any two values above.

In some embodiments, the mold filled with the silicon powder is placed under a condition for fourth pressure P₄ for a fourth pressure time T₄, and the fourth pressure P₄ and the fourth pressure time T₄ satisfy: 100 MPa≤P₄≤600 MPa, 3 min≤T₄≤6 min. In a case that the value of the fourth pressure P₄ (MPa) is 100, 150, 200, 250, 300, 350, 400, 450, 500, 550, 600 or a range between any two values above, the value of the fourth pressure time T₄ (min) is 3, 4, 5, 6, or a range between any two values above.

In some embodiments, at the end of the pressurization, a first pressure relief process is applied to the mold 1, and the first pressure relief process includes: reducing the pressure to a fifth pressure P₅ and maintaining the fifth pressure P₅ for a Tₙ time, wherein the fifth pressure P₅ and the Tₙ time satisfy: 10 MPa≤P₅≤100 MPa, 1 min≤Tₙ≤2 min. The value of the fifth pressure P₅ (MPa) may be 10, 20, 30, 40, 50, 60, 70, 80, 90, 100, or a range between any two values above. The value of Tₙ (min) may be 1, 1.5, 2, or a range between any two values above. According to the present application, the fifth pressure P5 is maintained at the end of the pressurization, resulted in a reduced amount of dust due to crush of the molded silicon block.

In some embodiments, the pressure relief rate v₂ satisfies 20 MPa/s≤v₂≤30 MPa/s. For example, the value of the pressure relief rate v₂ (MPa/s) may be 20, 25, 30, or a range between any two values above.

In some embodiments, the pressure range during the pressurization is controlled by selection of a first boosting rate or pressure relief rate according to the present application.

In some embodiments, the pressure time excludes the time for the pressure boosting process or the pressure relief process.

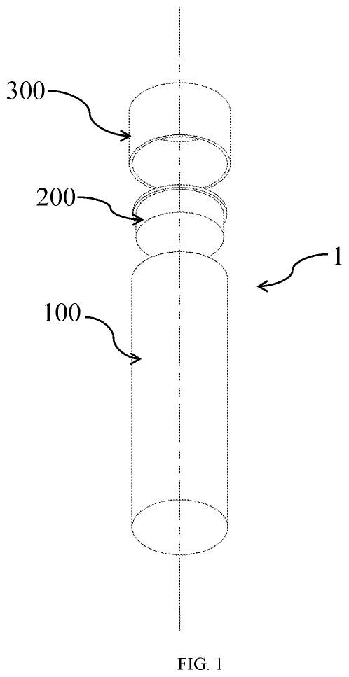

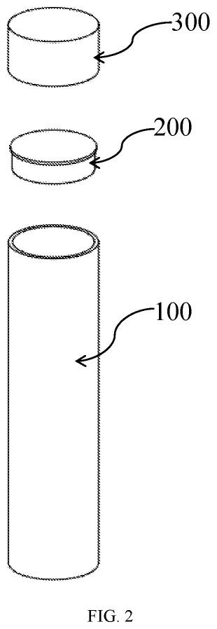

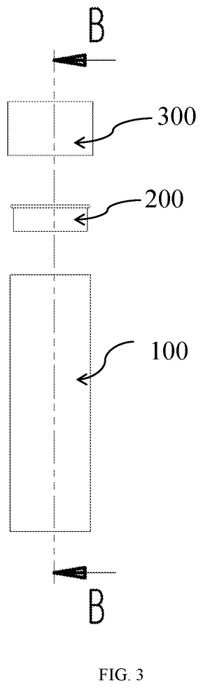

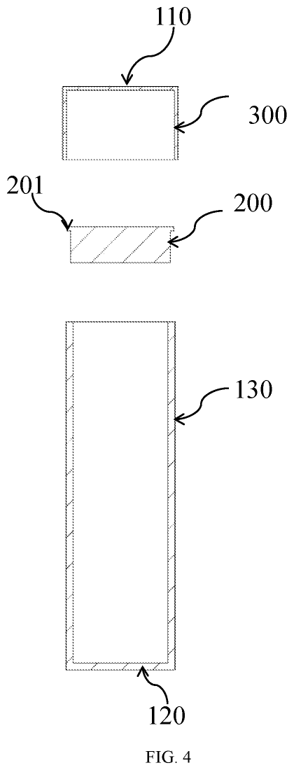

As shown in FIGS. 1 to 4, in some embodiments, the mold 1 is made of a polyurethane material, and the polyurethane material has a density ρ₀ satisfying:

$$1. g / {cm}^{3} \leq {ρ}_{0} \leq 10.1 g / {cm}^{3} .$$

In some embodiments, the mold 1 includes a cover 200 and a cylinder 100, the cover 200 covers the cylinder 100, and the silicon powder is filled in the cylinder 100.

In some embodiments, the cylinder 100 has an inner diameter ranging from 137 mm to 141 mm.

In some embodiments, the cylinder 100 has an outer diameter ranging from 154 mm to 160 mm.

In some embodiments, the cylinder 100 has a height ranging from 691 mm to 697 mm.

In some embodiments, a protective sleeve 300 is provided on the outer periphery of the cover 200, and the protective sleeve 300 covers over at least a portion of the cover 200.

In some embodiments, the protective sleeve 300 is provided over the outer periphery of the cover 200 for compaction.

In some embodiments, the pressurization method used in the present application is an isostatic pressing technique. During the operation, the cover 200 of the mold 1 is opened, the mold 1 is filled with the silicon power, and then the cover 200 is covered on the mold 1 for press-forming. Upon discharging, the cover 200 of the mold 1 is opened, and the silicon block formed in the mold 1 is pushed out by applying pressure to the bottom of the cylinder 100. This operation has a short period and is suitable for batch production.

In some embodiments, the edge of the cover 200 includes a step 201 that surrounds the periphery of the cover 200, and the step 201 further increases the sealability of the cover 200 to avoid leakage of silicon powder.

In some embodiments, the wear rate G of the mold 1 satisfies: G<G₀, wherein G₀ is the material decrement in g/cm², and G₀ satisfies: 0<G₀≤0.1 g/cm².

In some embodiments, G₀ represents the decrease in material measured by the wear tester under the specified conditions, and G₀ is expressed in units of g/cm².

The present application further provides a silicon block prepared by the above method.

In some embodiments, the silicon block is crushed to form first particles, the mass percentage of the first particles in the silicon block is equal to or greater than 97%, and the particle size D₁ of each of the first particles satisfies: 10 mm≤D₁.

In some embodiments, the particle size D₁ of the first particle satisfies: 10 mm≤D₁≤150 mm, for example, the value of the particle size of the first particle may be 10, 20, 30, 40, 50, 60, 70, 80, 90, 100, 110, 120, 130, 140, 150, or a range between any two values above. In other embodiments, the particle size D₁ (mm) of the first particle satisfies: 10 mm≤D₁≤70 mm.

In some embodiments, the silicon block is crushed to form second particles, the mass percentage of the second particles in the silicon block is equal to or less than 3%, and the particle size D₂ of each of the second particles satisfies: D₂<10 mm. In a case that the particle size of the second particle satisfies 3 mm≤D₂<10 mm, the mass percentage ranges from 2% to 3%, and in a case that the particle size of the second particles satisfies 0 mm≤D₂<3 mm, the mass percentage is equal to or less than 1%. According to the present application, the molded silicon block has reasonable particle size distribution after crushing, and the reasonable particle distribution is provided in the process of preparing and feeding the Czochralski single crystal, so that the feeding operation is facilitated.

The crushing operation in the present application can be manual crushing or mechanical vibration crushing. In some embodiments, manual crushing is employed.

The present application employs a dry pressing technique, to avoid pollution of raw materials, produce rapidly on a large scale, improve production efficiency, and achieve the application of the prepared silicon block in the production of Czochralski single crystal.
Example 1: a raw polycrystalline silicon powder is charged into a mold 1, as shown in FIG. 1 to FIG. 4, and the mold 1 of the present application is made of a polyurethane material. After charging, the silicon powder at the opening for charging is scraped or flattened by using a scraper, and the mold 1 is sealed by the cover 200 and the protective sleeve 300. After the sealing, the mold 1 is wound outside by the diaphragm to form a separate cavity, and the mold 1 is separated from a pressurized environment. The mold 1 filled the raw polycrystalline powder is placed into a device, and the liquid is injected to a set height, and then the device is operated. During operation of the device, the pressure is boosted to 100 MPa at a boosting rate of 20 MPa/s, and the pressure time lasts for 15 min. At the end of the pressurization, the pressure is relieved by 30 Mpa/s, and after returning to normal pressure, the liquid is drawn out from the furnace and the mold 1 is taken out. During the pressing process, the liquid uniformly transmits the pressure to each side of the mold 1, and the pressure deviation of either side of the mold 1 is in the range of +5 MPa. Surfaces of the mold 1 are washed with pure water, residual pure water on the surfaces of the washed mold 1 wiped, and the mold 1 is unsealed and demolded. Sealing package.
Examples 2 to 4: the pressurization method is same as in Example 1, except that the value of the pressure for and the pressure time are adjusted. Specific parameters are detailed in Table 1.
Comparative Example 1: the pressurization method is same as in Example 1, except that the value of the pressure and the pressure time are adjusted. Specific parameters are detailed in Table 1.
Comparative Example 2: silicon powder is not pressurized.

### Calculation Method:

The charge ratio=(B+C)/A*100%, wherein A is theoretical charge amount of the crucible in kg; B is mass of the block crushed in kg, wherein the block is formed by pressing silicon powder; and C is mass of other materials such as doping elements in kg.

TABLE 1
preparation parameters and results of Examples
1 to 4 and Comparative Examples 1 to 2

| | First pressure P1 | First pressure time | Pellet density | Charge ratio |
|---|---|---|---|---|
| | (Mpa) | T1 (min) | (g/cm³) | (%) |
| Example 1 | 100 | 15 | 2.0 | 100 |
| Example 2 | 300 | 10 | 2.0 | 100 |
| Example 3 | 600 | 7 | 2.0 | 100 |
| Example 4 | 50 | 16 | 1.2 | 30 |
| Comparative | 650 | 5 | 2.3 | 100 |
| Example 1 | | | | |
| Comparative | / | / | 0.1 | 6 |
| Example 2 | | | | |

As can be seen from the data of Examples 1 to 4 and Comparative Examples 1 to 2, the method of the present application increases the charge ratio from 6% in the silicon powder state to 100%. As can be seen from the data of Example 4, with a low pressure for pressurization, although the charge ratio is increased somewhat, the pellet density of the silicon block is affected, and labor time is consumed. As can be seen from the data of Comparative Example 1, increase in the pressure for pressurization does not affect the pellet density of the product, but too much increase affects the life of the device and causes difficulty in crushing the silicon block after molding.
Example 5: The preparation method is same as in Example 1, except that the pressure for pressurization and the pressure time for pressurization are adjusted so that the pressure is boosted to 50 MPa at a boosting rate of 20 MPa/s, and the pressure time lasts for 3 min. At the end of the pressurization, the pressure is boosted to 300 MPa at the boosting rate of 20 MPa/s, and the pressure time lasts for 6 min. The detailed parameters are shown in Table 2.
Examples 6 to 15: preparation method is same as Example 5, except that the pressure for pressurization and the pressure time for pressurization are adjusted, and the specific parameters are detailed in Table 2.

TABLE 2
preparation parameters and results of Examples 5 to 15

| | | | | | Pellet | Charge |
|---|---|---|---|---|---|---|
| | P₂ | T₂ | P₃ | T₃ | density | ratio |
| | (MPa) | (min) | (MPa) | (min) | (g/cm³) | (%) |
| Example 5 | 50 | 3 | 300 | 6 | 2.1 | 100 |
| Example 6 | 100 | 5 | 300 | 6 | 2.1 | 100 |
| Example 7 | 150 | 5 | 300 | 6 | 2.1 | 100 |
| Example 8 | 200 | 7 | 300 | 6 | 2.1 | 100 |
| Example 9 | 130 | 3 | 300 | 6 | 2.2 | 100 |
| Example 10 | 180 | 6 | 300 | 6 | 2.2 | 100 |
| Example 11 | 150 | 5 | 200 | 6 | 2.1 | 100 |
| Example 12 | 150 | 5 | 500 | 4 | 2.1 | 100 |
| Example 13 | 150 | 5 | 600 | 5 | 2.0 | 100 |
| Example 14 | 150 | 5 | 100 | 3 | 2.0 | 100 |
| Example 15 | 150 | 5 | 650 | 9 | 2.3 | 100 |

As can be seen from the results of Table 2, the present application increases the pellet density by controlling the pressure and pressure time for the pressurization. The amount of dust due to crushing the silicon block obtained from Examples 5 to 15 is less than the silicon blocks from Examples 1 to 4.
Example 16: the preparation method is same as in Example 1, except that the pressure and the pressure time are adjusted so that the pressure is boosted to 50 MPa at a boosting rate of 20 MPa/s, and the pressure time lasts for 3 min. At the end of the pressurization, the pressure is boosted to 300 MPa at a boosting rate of 20 MPa/s, and the pressure time lasts for 6 min. The pressure is subsequently maintained at 300 MPa and the pressure time is continued for 4 min. Detailed parameters are given in Table 3.
Examples 17 to 31: preparation method is same as Example 16, except that the pressure for pressurization and the pressure time for pressurization are adjusted, and the specific parameters are detailed in Table 3.

TABLE 3
preparation parameters and results of Examples 16 to 31

| | | | | | | | Pellet | Charge |
|---|---|---|---|---|---|---|---|---|
| | P₂ | T₂ | P₃ | T₃ | P₄ | T₄ | density | ratio |
| | (Mpa) | (min) | (Mpa) | (min) | (Mpa) | (min) | (g/cm³) | (%) |
| Example 16 | 50 | 3 | 300 | 6 | 300 | 4 | 2.2 | 100 |
| Example 17 | 100 | 5 | 300 | 6 | 300 | 4 | 2.2 | 100 |
| Example 18 | 150 | 5 | 300 | 6 | 300 | 4 | 2.3 | 100 |
| Example 19 | 200 | 7 | 300 | 6 | 300 | 4 | 2.2 | 100 |
| Example 20 | 70 | 3 | 300 | 6 | 300 | 4 | 2.2 | 100 |
| Example 21 | 160 | 6 | 300 | 6 | 300 | 4 | 2.2 | 100 |
| Example 22 | 150 | 5 | 200 | 6 | 300 | 4 | 2.2 | 100 |
| Example 23 | 150 | 5 | 500 | 4 | 300 | 4 | 2.3 | 100 |
| Example 24 | 150 | 5 | 600 | 5 | 300 | 4 | 2.3 | 100 |
| Example 25 | 150 | 5 | 100 | 3 | 300 | 4 | 2.0 | 100 |
| Example 26 | 150 | 5 | 700 | 9 | 300 | 4 | 2.4 | 100 |
| Example 27 | 150 | 5 | 300 | 6 | 100 | 5 | 2.2 | 100 |
| Example 28 | 150 | 5 | 300 | 6 | 300 | 6 | 2.2 | 100 |
| Example 29 | 150 | 5 | 300 | 6 | 600 | 3 | 2.0 | 100 |
| Example 30 | 150 | 5 | 300 | 6 | 50 | 2 | 2.2 | 100 |
| Example 31 | 150 | 5 | 300 | 6 | 650 | 7 | 2.3 | 100 |

As can be seen from the results of Table 3, the present application increases the pellet density by controlling the pressure and pressure time for the pressurization. The amount of dust due to crushing the silicon block obtained from Examples 16 to 31 is less than the silicon blocks from Examples 5 to 15.
Example 32: the preparation method is same as in Example 1, except that the pressure for pressurization and the pressure time for pressurization are adjusted so that the pressure is boosted to 50 MPa at a boosting rate of 20 MPa/s, and the pressure time lasts for 3 min. At the end of the pressurization, the pressure is boosted to 300 MPa at a boosting rate of 20 MPa/s, and the pressure time lasts for 6 min. Then the pressure is maintained at 300 MPa, the pressure time is continued for 6 min, and then the pressure is reduced to 50 MPa at a pressure relief rate 20 MPa/s, and the pressure time lasts for 1.5 min, detailed in Table 4.
Examples 33 to 50: the preparation method is same as Example 32, except that the pressure for pressurization and the pressure time for pressurization are adjusted, and the specific parameters are detailed in Table 4.

TABLE 4
preparation parameters and results of Examples 32 to 50

| | | | | | | | | | Pellet | Charge |
|---|---|---|---|---|---|---|---|---|---|---|
| | P₂ | T₂ | P₃ | T₃ | P₄ | T₄ | P₅ | T₅ | density | ratio |
| | (Mpa) | (min) | (Mpa) | (min) | (Mpa) | (min) | (Mpa) | (min) | (g/cm³) | (%) |
| Example 32 | 50 | 3 | 300 | 6 | 300 | 6 | 50 | 1.5 | 2.4 | 100 |
| Example 33 | 100 | 5 | 300 | 6 | 300 | 6 | 50 | 1.5 | 2.4 | 100 |
| Example 34 | 150 | 5 | 300 | 6 | 300 | 6 | 50 | 1.5 | 2.5 | 100 |
| Example 35 | 200 | 7 | 300 | 6 | 300 | 6 | 50 | 1.5 | 2.5 | 100 |
| Example 36 | 80 | 3 | 300 | 6 | 300 | 6 | 50 | 1.5 | 2.2 | 100 |
| Example 37 | 180 | 7 | 300 | 6 | 300 | 6 | 50 | 1.5 | 2.2 | 100 |
| Example 38 | 150 | 5 | 200 | 6 | 300 | 6 | 50 | 1.5 | 2.1 | 100 |
| Example 39 | 150 | 5 | 500 | 4 | 300 | 6 | 50 | 1.5 | 2.4 | 100 |
| Example 40 | 150 | 5 | 600 | 5 | 300 | 6 | 50 | 1.5 | 2.5 | 100 |
| Example 41 | 150 | 5 | 100 | 7 | 300 | 6 | 50 | 1.5 | 2.2 | 100 |
| Example 42 | 150 | 5 | 400 | 8 | 300 | 6 | 50 | 1.5 | 2.5 | 100 |
| Example 43 | 150 | 5 | 300 | 6 | 100 | 4 | 50 | 1.5 | 2.3 | 100 |
| Example 44 | 150 | 5 | 300 | 6 | 500 | 6 | 50 | 1.5 | 2.4 | 100 |
| Example 45 | 150 | 5 | 300 | 6 | 600 | 5 | 50 | 1.5 | 2.5 | 100 |
| Example 46 | 150 | 5 | 300 | 6 | 200 | 3 | 50 | 1.5 | 2.1 | 100 |
| Example 47 | 150 | 5 | 300 | 6 | 400 | 4 | 50 | 1.5 | 2.5 | 100 |
| Example 48 | 150 | 5 | 300 | 6 | 300 | 6 | 10 | 1 | 2.3 | 100 |
| Example 49 | 150 | 5 | 300 | 6 | 300 | 6 | 70 | 1.5 | 2.4 | 100 |
| Example 50 | 150 | 5 | 300 | 6 | 300 | 6 | 100 | 2 | 2.5 | 100 |

As can be seen from the results of Table 4, in the present application, the pellet density of the silicon powder can be increased by applying pressure during forming the silicon powder. From the results on crushing the molded silicon block, the pressure relief step affects less on the pellet density, however, the dust is significantly reduced in crushing compared to the silicon powder formed without the pressure relief step.

The present application increases the pellet density by controlling the pressure range and pressure time for the pressurization. In addition, the particle size distribution range of the silicon block crushed after preparing by the present application can be directly used for feeding, and no dust pollution is generated during crushing.

The above describes in detail a silicon powder forming method, a silicon block and a use thereof provided in the present application. Specific examples are used to illustrate the principles and embodiments of the present application. The description of the above examples is merely provided to help understand the method and the core idea of the present application. At the same time, variations will occur to those skilled in the art in both the detailed description and the scope of application in accordance with the teachings of the present application. In view of the foregoing, the present description should not be construed as limiting the application.

1. A silicon powder forming method, comprising:
placing a mold filled silicon powder in a condition for first pressure P₁ for a first pressure time T₁ to obtain a silicon block, wherein the first pressure P₁ and the first pressure time T₁ satisfy: 50 MPa≤P₁≤600 MPa, 7 min≤T₁≤15 min.

2. The silicon powder forming method of claim 1, wherein the condition for first pressure P₁ is achieved by boosting, and the boosting comprises: boosting a pressure to the first pressure P₁ at a first boosting rate v₁, wherein the first boosting rate v₁ satisfies: 20 MPa/s≤v₁≤30 MPa/s; and/or the mold (1) filled with the silicon powder is placed in a closed environment prior to the condition for first pressure P₁.

3. The silicon powder forming method of claim 1, wherein the first pressure P₁ is applied by a pressurizing medium, the pressurizing medium is a fluid, and the mold filled with the silicon powder is placed in a cavity prior to the condition for first pressure P₁; and
the mold and the pressurizing medium are separated by the cavity; or the pressurizing medium is filled in the cavity, and the mold is in contact with the pressurizing medium.

4. The silicon powder forming method of claim 3, wherein in a case that the mold and the pressurizing medium are separated by the cavity, the pressurizing medium is a liquid; and in a case that the pressurizing medium is filled in the cavity, and the mold is in contact with the pressurizing medium, the pressurizing medium is gas; and/or,
in the case that the mold and the pressurizing medium are separated by the cavity, an interior of the cavity maintains a dry environment with a temperature ranging from 20° C. to 25° C. and a humidity ranging from 40% rh to 50% rh.

5. The silicon powder forming method of claim 1, wherein the silicon powder has a particle size of 0.1 μm to 1000 μm.

6. The silicon powder forming method of claim 1, wherein the mold comprises a first side, a second side, and a third side; the first side is disposed opposite to the second side, the first side is connected to the second side by the third side, and the first side and the third side receive the first pressure P₁; and/or,
the first side, the second side, and the third side receive the first pressure P₁, and a pressure deviation PD applied to the first side, the second side, and the third side satisfies: −5 MPa≤PD≤5 MPa.

7. The silicon powder forming method of claim 1, wherein the mold comprises a cover and a cylinder, the cover covers the cylinder, and the silicon powder is filled in the cylinder; and/or,
the mold comprises a protective sheet provided on an outer periphery of the cover, the protective sheet covers at least a part of the cover; and/or,
an edge of the cover has a step, and the step surrounds the cover.

8. The silicon powder forming method of claim 1, wherein the mold is made of a polyurethane material, and the polyurethane material has a density ρ₀ satisfying: 1.00 g/cm³≤ρ₀≤1.01 g/cm³.

9. The silicon powder forming method of claim 1, wherein wear rate G of the mold satisfies: G<G₀, wherein G₀ is material decrement in g/cm², and
G₀ satisfies: 0<G₀≤0.1 g/cm².

10. The silicon powder forming method of claim 1, further comprising:
placing the mold filled with the silicon powder to a second pressure P₂ for a second pressure time T₂, wherein the second pressure P₂ and the second pressure time T₂ satisfy: 50 MPa≤P₂≤200 MPa, 3 min≤T₂≤7 min; and
placing the mold filled with the silicon powder to a third pressure P₃ for a third pressure time T₃, wherein the third pressure P₃ and the third pressure time T₃ satisfy:
$$200 MPa \leq {P}_{3} \leq 600 MPa , 4 min \leq {T}_{3} \leq 8 min .$$

11. The silicon powder forming method of claim 10, further comprising:
placing the mold filled with the silicon powder to a fourth pressure P₄ for a fourth pressure time T₄, wherein the fourth pressure P₄ and the fourth pressure time T₄ satisfy: 100 MPa≤P₄≤600 MPa, 3 min≤T₄≤6 min.

12. The silicon powder forming method of claim 1, further comprising, at end of pressurization, applying a first pressure relief process to the mold, wherein the first pressure relief process comprises reducing the pressure to a fifth pressure P₅ for a time Tₙ, and the fifth pressure P₅ and the time Tₙ satisfy: 10 MPa≤P₅≤100 MPa, 1 min≤Tₙ≤2 min.

13. A silicon block,
wherein the silicon block first particles, mass percentage of the first particles in the silicon block is equal to or greater than 97%, and a particle size D₁ of each of the first particles satisfies: 10 mm≤D₁; and/or,
the silicon block is crushed to form second particles, mass percentage of the second particles in the silicon block is equal to or less than 3%, and a particle size D₂ of each of the second particles satisfies: D₂<10 mm.

15. A use of the silicon block of claim 13 in production of Czochralski single crystal.
